(19) United States
(12) Patent Application Publication
(10) Pub. No.: US 2019/0101126 A1
(43) Pub. Date: Apr. 4, 2019

(54) INSTA FAN CELL PHONE ATTACHMENT

(71) Applicant: Kim Porter, Toluca Lake, CA (US)

(72) Inventor: Kim Porter, Toluca Lake, CA (US)

(21) Appl. No.: 16/121,612

(22) Filed: Sep. 4, 2018

Related U.S. Application Data
(60) Provisional application No. 62/553,419, filed on Sep. 1, 2017.

(51) Int. Cl. F04D 25/06; H04M 1/02; H05K 7/20; A45C 11/00; F04D 19/00; F04D 29/64

(52) U.S. Cl. CPC F04D 25/0673; H04M 1/0202; H05K 7/20172; A45C 2011/002; F04D 19/002; F04D 29/646; A45C 11/00

(57) ABSTRACT

Cell Phone Attachment providing a compact, battery-powered, rechargeable personal cooling fan that either clips onto a smartphone or is incorporated into a new design for a smartphone case. In either version, the Insta Fan provides an instant, cooling breeze, whether for cooling off or for achieving that “hair-in-the-breeze” selfie.

### CLAIM OF PRIORITY

This patent application claims priority under 35 USC 119 (e) (1) from U.S. Provisional Patent Application Ser. No. 62/553,419, filed Sep. 1, 2017, of common inventorship herewith entitled, “INSTA FAN,” which is incorporated herein by reference as though the same were set forth in its entirety.

### FIELD OF THE INVENTION

The present invention pertains to the field of smartphone fans, and more specifically to the field of smartphone fans providing a cooling fan that either clips onto a smartphone, or is incorporated into a new design for a smartphone case.

### BACKGROUND OF THE INVENTION

A “selfie” is a self-portrait taken with a smartphone camera made possible by the smartphone camera, texting, and the social networking and photo-sharing sites of the Internet. Selfies make up more than 30 percent of the photos taken by people aged 18-24. And, the word “selfie” was announced as being the “word of the year” by the Oxford English Dictionary, noting that the word itself had an Australian origin. The selfie has become a ubiquitous feature of contemporary life for a fast, easy way to express yourself, control the way you are represented, and share your image with the world.

Consider, further, that high-fashion photographers regularly use electric fans to give models a glamorous “hair-in-the-breeze” look; and, finally, that on hot, windless days in summer, anyone would enjoy having a “personal breeze” to cool themselves off with.

The prior art has put forth several designs for fans. Among these are:

US Patent Application No. 2011/0194252 to Eric Wang provides a personal cooling fan is integrated into a mobile electronic device. The mobile electronic device has a vibration alert system that includes control circuitry to control a vibration motor, and the personal cooling fan system is also controlled by the control circuitry. The personal cooling fan system includes a rotary motor contained within a housing of the device, a drive shaft having a first portion engaged by the rotary motor and having a second portion protruding from the housing, and fan blades removably attached to the second portion of the drive shaft such that the rotary motor is operable to rotate the drive shaft thereby spinning the fan blades. The drive shaft may be extended from the housing to attach the fan blades and operate the fan, and retracted into the housing when the fan is not in use.

U.S. Pat. No. 7,782,613 to Scott C. Harris provides a cellular cooling part includes a number at least one movable part, that can be the removable flap or movable cover for a fan. The fan, for example, can be moved or opened to expose it. A flap can also be opened. In addition, different covering structures can be used.

U.S. Pat. No. 7,880,586 to Gustav Fagrenius provides a cooling system for a mobile terminal for wireless communication comprising a rotating fan for reducing the heat generated by the mobile terminal and at least one weight for causing an unbalance of the rotation of the fan in order to cause vibration of the fan, whereby said weight is activated when the rotational speed of the fan exceeds a predefined level.

None of these prior art references describe the present invention.

### SUMMARY OF THE INVENTION

It is an object of the present invention to providing a smartphone fan that either clips onto a smartphone, or is incorporated into a new design for a smartphone case.

### BRIEF DESCRIPTION OF THE DRAWINGS

FIG. 1 is a front view illustrating a smartphone case having an integrated cooling fan, constructed in accordance with the present invention, showing the air vents along the front perimeter of the phone case allowing the egress of air therethrough.

FIG. 2 is a rear perspective view illustrating the smartphone case having an integrated cooling fan, constructed in accordance with the present invention.

FIG. 3 is a front perspective view illustrating another embodiment of the cooling fan, constructed in accordance with the present invention, showing the cooling fan clipped onto the upper edge of a smartphone.

FIG. 4 is a side view of a cell phone having the cooling fan clipped onto a smartphone.

### DETAILED DESCRIPTION OF THE INVENTION

Please refer to the drawings. As used herein the term “cell phone” and “smart phone” are used interchangeably. The present invention is an Insta Fan Cell Phone Attachment 10, or simply Insta Fan, providing a compact, battery-powered, rechargeable personal cooling fan 14 that either clips onto a smartphone 20, or is incorporated into a new design for a smartphone case 30. In either version, the Insta Fan provides an instant, cooling breeze, whether for cooling off or for achieving that “hair-in-the-breeze” selfie.

The Insta Fan can be produced in two distinct versions. Both versions of the Insta Fan are powered by a long-life, compact, rechargeable lithium-ion battery (not shown); and both are rechargeable via an included power adapter and USB- to mini-USB cord. Both versions employ small, plastic-bladed, rotary electric fans 14. Both versions feature a single-button 18 for ON/OFF; and three-speed operation control 16 capable of Low, Medium, and High speeds. Both the clip-on and the phone-case versions can also be produced in a wide variety of colors, textures, and finishes to meet the range of user tastes.

The difference between the two versions will be explained.

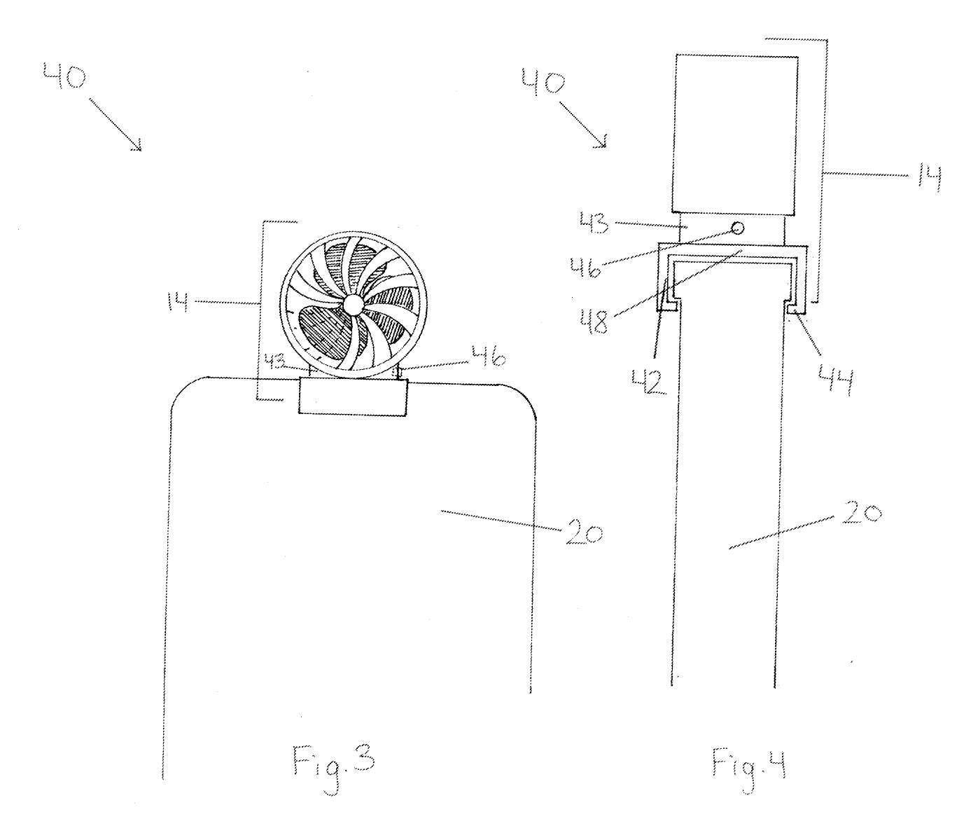

In an embodiment, the device is a clip-on accessory 40, shown in FIGS. 3 and 4. Clip on cell phone fan 40 fastens to the phone 20 or case by means of a spring-loaded clip 42. Clip 42 is configured in the shape of a U-shaped clip wherein the arms of the “U” terminate in a protruding lip 44 along its lower edge, further wherein protruding lip 44 engages the edge of the phone 20 or cell phone case. Fan 14 is mounted to the base 48 of the “U” which abuts the top edge of the phone 20 or case. Fan 14 is mounted to clip 42 by neck 43. In addition to providing support for fan 14 to be securely mounted to phone 20, neck 43 further comprises a charging port 46. In an embodiment, the clip-on Insta Fan is rectangular, approximately 1 to 1% inches in width and length, and approximately %- to 1 inch in thickness or depth, and could be clipped onto the phone in any position. This version of the Insta Fan includes the fan-and-clip, the charging adapter and cord, and a convenient zippered pouch for easy portability and storage.

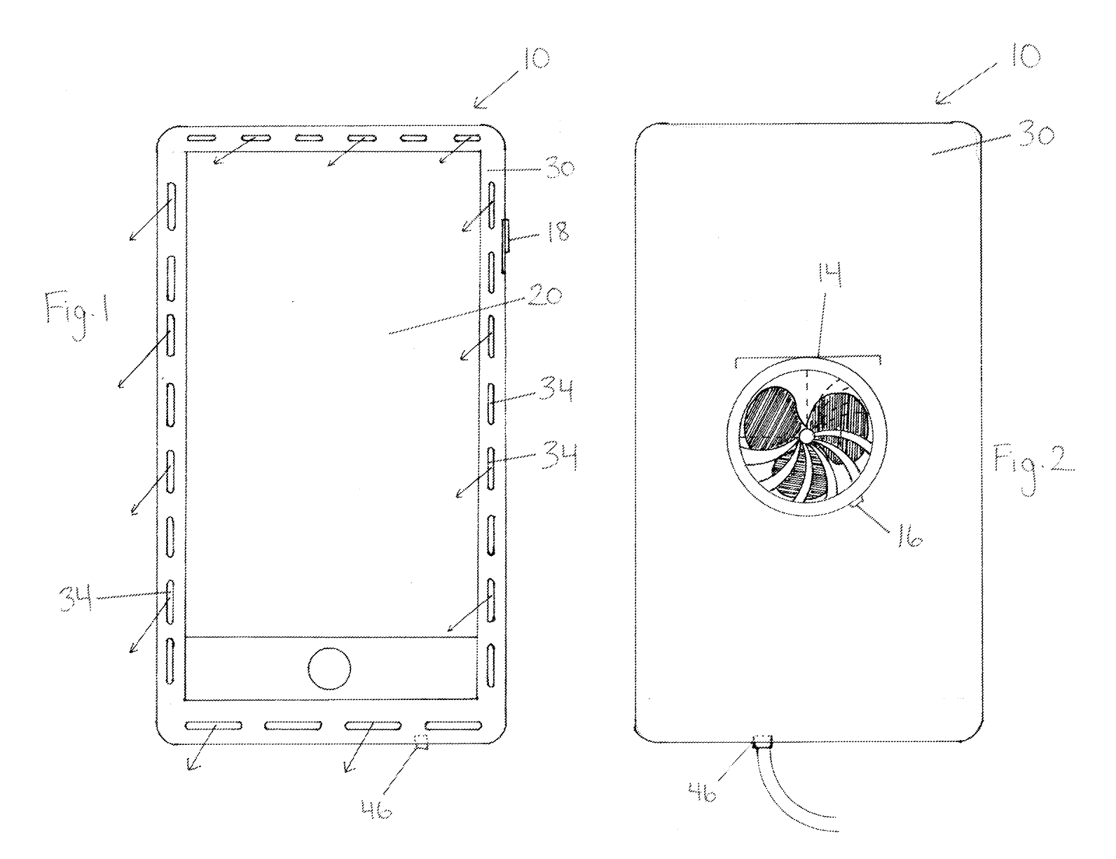

An alternative embodiment is shown in FIGS. 1 and 2. Phone case 30, comprises openings 34 spaced along the perimeter edge of the front side through which openings 34 the fan 14 mounted to the back of the phone case 30, pushes air.

The Insta Fan phone-case(s) are produced in a variety of sizes to correspond with the most popular smartphones, generally ranging between 4¼ and 7½ inches in height, and 2½ to 3 inches in width. The case is form-fitting to the phone, and fabricated in a resilient but durable molded plastic polymer. The Insta Fan phone case features a regular series of openings 34 or vents around the phone's front-side borders, with the fan 14 situated in the back of the phone case 30. If it is determined, that space is required for the generated air to move from the back of the phone to the spaces in the front, the Insta Fan case can be made to be somewhat thicker than other smartphone cases with a depth or thickness of approximately 1 inch.

Phone case 30 further comprises charging port 46.

Both the clip-on Insta Fan and the phone-case Insta Fan can comprise indicia or other logo such as an attractive, stylized “IF” logo, for example.

In the Insta Fan, one can reach for a smartphone not just to check the temperature, but to change it for there's nothing like a fresh breeze to make a hot day feel a little cooler. And for those who want to add flair, panache and drama to their selfies, the Insta Fan delivers just the breeze to achieve that high-fashion, slightly windblown look. Whether in the clip-on version or the phone-case version, the Insta Fan converts one's smartphone, instantly, into a compact personal fan; and this smartphone accessory is sure to make a hot day a little cooler, and a selfie a lot more striking.

Although this invention has been described with respect to specific embodiments, it is not intended to be limited thereto and various modifications which will become apparent to the person of ordinary skill in the art are intended to fall within the spirit and scope of the invention as described herein taken in conjunction with the accompanying drawings and the appended claims.

1. A smartphone attachment comprising a cooling fan that clips onto a smartphone or smartphone case, wherein the attachment is a compact, battery-powered, rechargeable personal cooling fan, and wherein the attachment clips onto a cell phone or phone case by means of a clip.

2. The smartphone attachment of claim 1, wherein the clip is configured in the shape of a U-shaped clip and wherein the arms of the “U” terminate in a protruding lip along its lower edge, further wherein protruding lip engages the edge of the phone or cell phone case.

3. The smartphone attachment of claim 2, wherein a fan is mounted to the clip at the base of the “U,” which base abuts the top edge of the phone or case.

4. The smartphone attachment of claim 2, wherein a fan is mounted to the clip by a neck.

5. The smartphone accessory of claim 4, further wherein the neck comprises a charging port and the battery is a lithium-ion battery.

6. The smartphone attachment of claim 3, wherein the accessory is rectangular, approximately 1 to 1½ inches in width and length, and approximately ¾- to 1 inch in thickness or depth.

7. The smartphone attachment of claim 6, wherein the attachment is capable of attaching to the phone or case in any position.

8. The smartphone accessory of claim 2, further comprising a control button for ON and OFF.

9. The smartphone accessory of claim 2, further comprising a speed High, Medium and Low.

10. A smartphone case comprising a fan mounted to the back of the case and case and further comprises openings spaced along the perimeter edge of the front side of the case through which openings the fan mounted to the back of the phone case, pushes air.

11. The smartphone case of claim 10, wherein the case is form-fitting to the phone, and fabricated in a resilient and durable molded plastic polymer.

12. The smartphone case of claim 10 produced in any one of a wide variety of colors, textures, and finishes to meet the range of user tastes.

13. The smartphone case of claim 10 produced in any one of a a variety of sizes to correspond with the most popular smartphones, generally ranging between 4¼ and 7½ inches in height, and 2½ to 3 inches in width.
